(19) United States
(12) Patent Application Publication
(10) Pub. No.: US 2003/0212932 A1
(43) Pub. Date: Nov. 13, 2003

(54) Remote diagnostic packets

(76) Inventors: William F. Sauber, Georgetown, TX (US); Rey G. Carolina, Austin, TX (US)

Correspondence Address: Baker Botts L.L.P., One Shell Plaza, 910 Louisiana, Houston,, TX, 77002-4995, US

(21) Appl. No.: 10/142,033

(22) Filed: May 9, 2002

(51) Int. Cl. G01R 31/28

(52) U.S. Cl. 714/712

(57) ABSTRACT

A method of performing a remote diagnostic test on an information handling system that is connected to a network and is responsive to test mode packets is disclosed. The method includes transmitting a test mode packet to the information handling system via a network, transmitting a test command packet to the information handling system via the network; and receiving a test result via the network. Additionally, the method includes receiving a test mode packet via a network, where the test mode packet is configured to place a device of the information handling system in an operational state, receiving a test command packet via the network, where the test command packet causing a test to be performed on the information handling system, and transmitting the test results of the test via the network.

### BACKGROUND OF THE INVENTION

1. Field of the Invention

The present invention relates generally to information handling systems. More specifically, the present invention relates to remotely diagnosing an information handling system that is connected to a network of information handling systems.

2. Description of the Related Art

Remote diagnosis of failed information handling systems generally involves a remote host logging on to the failed system to perform a series of diagnostic tests to isolate, and possibly correct the failure. Execution of the diagnostics is performed by a processor within the failed system. In a local networked environment, such as a corporate network, diagnostic support for failed systems is generally local and relies on the failed system itself to independently perform self diagnostic tests. However, this approach generally requires the availability of the information handling system's resources (e.g., a processor), which may or may not be in reliable and/or working order, depending on the extent of the failure. Additionally, it is difficult to perform diagnostic tests over a network in accordance with an existing test standard. Because of the impact a failed system may have on, for example productivity, fast results are needed, and the trend is to replace an entire system or multiple properly working assemblies of the failed information handling system, rather than perform a series of diagnostic tests to determine the true nature of the failure.

As the value and use of information continues to increase, individuals and businesses seek additional ways to process and store information in a reliable manner. One option available to users, introduced above, is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

A computer system, which is one common type of information handling system, may be designed to give independent computing power to one or a plurality of users. Computer systems may be found in many forms including, for example, mainframes, minicomputers, workstations, servers, clients, personal computers, Internet terminals, notebooks, personal digital assistants, and embedded systems.

A computer system may be available as a desktop, floor-standing unit, or as a portable unit. The computer system typically includes a microcomputer unit having a processor, volatile and/or non-volatile memory, a display monitor, a keyboard, one or more floppy diskette drives, a hard disc storage device, an optional optical drive, e.g., DVD, CD-R, CD-RW, Combination DVD/CD-RW or CD-ROM, and an optional printer. A computer system also includes a commercially available operating system, such as Microsoft Windows XP™ or Linux. A computer system may also include one or a plurality of peripheral devices such as input/output (“I/O”) devices coupled to the system processor to perform specialized functions. Examples of I/O devices include keyboard interfaces with keyboard controllers, floppy diskette drive controllers, modems, sound and video devices, specialized communication devices, and even other computer systems communicating with each other via a network. These I/O devices are typically plugged into connectors of computer system I/O interfaces such as serial interfaces and parallel interfaces, for example. Generally, these computer systems use a system board or motherboard to electrically interconnect these devices.

Several standards exist in the field of testing electrical devices and integrated circuits. The Joint Test Application Group (“JTAG”) was created in 1985 to create test standards for testing printed circuit boards and integrated circuit devices. The JTAG proposal was approved by IEEE as IEEE Standard 1149.1 in 1990. The IEEE standard 1149.1, which may also be referred to as the JTAG standard, generally specifies test connections, signals and protocols. IEEE has published subsequent updates to the 1149.1 standard. The Static Component Interconnect Test Technology (“SCITT”), which was launched by Philips Research and Fujitsu in 1998, is another widely accepted test standard.

During the manufacturing process of the information handling system, the information handling system typically undergoes a series of tests. The test equipment used to carry out the tests may use the JTAG or the SCITT standard for testing and diagnosing various components of the information handling system, such as the processor. The processor is typically placed in a test mode to conduct the tests.

The Advanced Configuration and Power Interface (ACPI) specification, Revision 2.0, Jul. 27, 2000, is published by Compaq Computer Corporation, Intel Corporation, Microsoft Corporation, Phoenix Technologies Ltd., and Toshiba Corporation and is used extensively in power management applications. For example, the ACPI specification defines a global system state which may be a “Power Down” mode with minimum power consumption. The system turns off most of the power supply but keeps the minimum power, which offers the “Wake-Up” devices to activate and reboot the system. The reboot procedure works as a cold start and activates the system. The Magic Packet Technology, which is well known, may be used to wake up computer systems included in a network from a remote host. Wakeup-on-LAN (“WOL”) is a more general implementation of this function.

As described earlier, conventional remote diagnostics systems have generally relied on two-way voice and/or data communication between a remote host, performing the diagnostic tests, and a failed or inoperative computer system to diagnose the problem. However, this typically requires the availability of the processor. For example, failure of the processor or internal system busses in systems with dedicated diagnostic processor may prevent fault identification and/or fault isolation.

It may be desirable to be able to perform diagnostics of an information handling system included in a network from a remote host using testing standards such as JTAG, SCITT in conjunction with WOL, preferably where the intelligence to perform the diagnostics is located on the remote host.

### SUMMARY OF THE INVENTION

Embodiments of the present invention generally provide for performing remote diagnostic tests of a target information handling system over a network using testing standards (such as JTAG and/or SCITT) in conjunction with “Wakeup-on-LAN” procedures.

Thus, in accordance with the present invention, a method and system of remotely diagnosing an information handling system operatively coupled to a network responsive to test mode packets is disclosed, including transmitting a test mode packet to the information handling system via a network, transmitting a test command packet to the information handling system via the network; and receiving a test result via the network. Additionally, the method and system includes receiving a test mode packet via a network, where the test mode packet is configured to place a device of the information handling system in an operational state, receiving a test command packet via the network, where the test command packet causing a test to be performed on the information handling system, and transmitting the test results of the test via the network.

The foregoing is a summary and thus contains, by necessity, simplifications, generalizations and omissions of detail; consequently, those skilled in the art will appreciate that the summary is illustrative only and is not intended to be in any way limiting. Other aspects, inventive features, and advantages of the present invention, as defined solely by the claims, will become apparent in the non-limiting detailed description set forth below.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a system architecture block diagram that is suitable for implementing a method for performing a diagnostic test on an information handling system in accordance with the present invention;

FIG. 2 shows a flow chart of a method for performing support functions for diagnostic testing of a target information handling system coupled to a network of information handling systems;

FIG. 3 shows an exemplary data structure for a packet of information in accordance with the present invention;

FIG. 4 shows a flow chart of a method for requesting diagnostic test support functions to be performed by a target information handling system coupled to a network of information handling systems; and

FIG. 5 shows one embodiment of a system suitable for implementing a method for performing support functions for remote diagnostic testing in accordance with the present invention.

### DETAILED DESCRIPTION

Embodiments of the present invention generally provide for performing remote diagnostic tests of a target information handling system. The remote diagnostic tests are performed over a network, obviating the need for on-site diagnostics. For example, in one embodiment, testing standards (such as JTAG and/or SCITT) used in conjunction with “Wakeup-on-LAN” procedures may be used to diagnose when, for example, one or all processors associated with the target information handling system are unavailable and/or nonfunctional.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

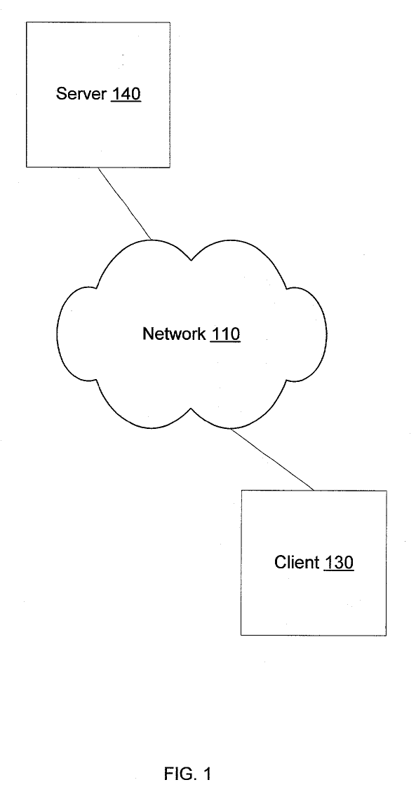

Referring to FIG. 1, a system architecture block diagram suitable for implementing a remote diagnostic test on an information handling system is illustrated. As shown, client 130 is coupled to a network 110, along with server 140. Client 130 may be experiencing problems which may arise as a result of an inoperative component (e.g., a processor) of client 130, while server 140 may be a host information handling system located at a customer service support center able to remotely diagnose client 130 in accordance with embodiments of the present invention. In one embodiment, client 130 is an information handling system configured to interface with network 110 and contains software instructions configured to be executed on one or more processing resources such as a central processing unit. Further, in one embodiment, server 140 is an information handling system also configured to interface with network 110 and contains software instructions configured to be executed on one or more processing resources such as a central processing unit.

Network 110 also includes other information handling systems (not shown) operating as servers and/or clients. In one embodiment, a minimum configuration network 110 includes two information handling systems, one configured as a server and the other configured as a client. Network communications between each of the information handling systems coupled to network 110 may be based on various well known technologies and/or standards such as dial-up modems, DSL, Ethernet, broadband, and fiber optic. Network 110 may also include various types and topologies of networks such as a local area network (“LAN”), wide area network (“WAN”), Internet, Intranet, token ring, wireless broadband or the like.

In such as case when a problem with client 130 does arise, and a customer calls a customer service support center to report the problem, server 140 is configurable to diagnose the problem remotely through network 110. In some embodiments, existing testing and communication standards such as JTAG and WOL maybe used. One of ordinary skill in the art will recognize that communication between the failed information handling system and the remote information handling system can also be performed over the internet, implementing functions similar to WOL therewith.

For example, in one embodiment, server 140 is configured to provide information describing one or more diagnostic tests to client 130. The provided diagnostic information may describe functions to be performed by server 140 which are necessary or useful in carrying out the diagnostic testing. The diagnostic information may also describe support functions performed by client 130 and executed by server 140. For example, the support functions may include, but are not limited to, extraction of JTAG information from a test command packet received from a host, comparing a received bit pattern to a predefined bit pattern, routing JTAG information to a designated device and/or component included in the target system, receiving JTAG information from the designated device and/or component, and preparing JTAG information to be sent to the requesting host in response to a received packet.

The support functions that may be required to be performed by the target system preferably do not depend on the availability of the processor included in client 130. In another embodiment, the diagnostic test is performed in compliance with the JTAG or the SCITT test standard. In one embodiment, the performance of the diagnostic test on server 140 may include determining the operational status of any or all JTAG compliant devices and/or components included in client 130. In yet another embodiment, the devices and/or components of client 130 may include one or more individual semiconductor devices and/or one or more PCI option cards compliant with a standard test interface (e.g., the JTAG standard).

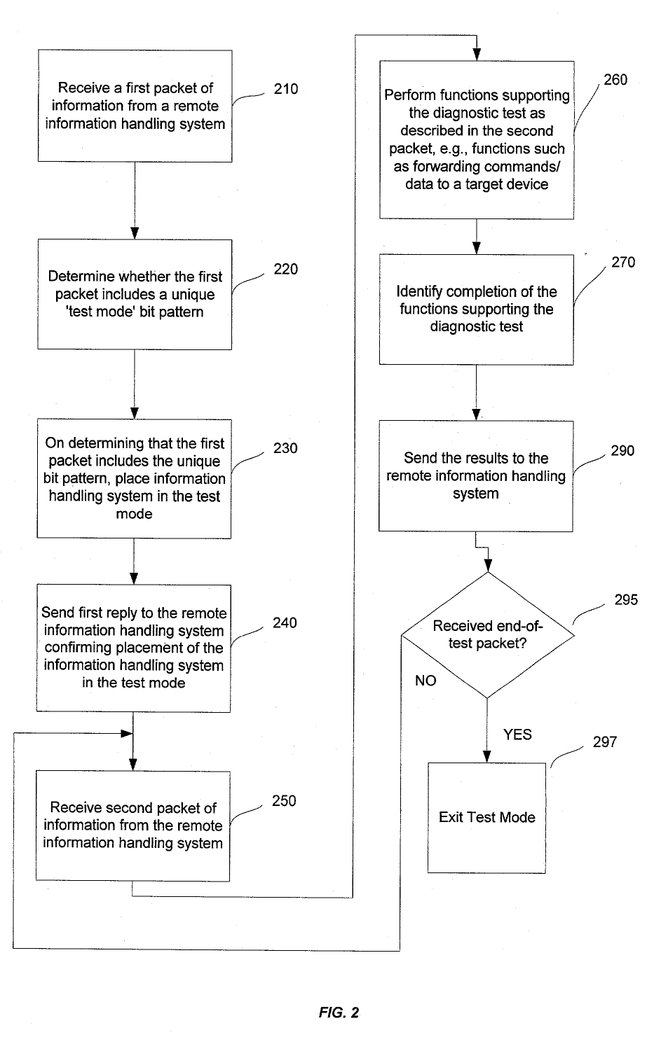

Referring now to FIG. 2, a flow chart illustrating a method for performing support functions for a diagnostic test of client 130 coupled to a network of information handling systems, is described according to one embodiment of the present invention.

In step 210, a first packet of information is received from server 140. The first packet of information relates to diagnostic test information used to diagnose a problem associated with client 130. In step 220, it is determined whether the first packet of information includes a unique bit pattern and/or a unique message or a command, e.g., similar to a WOL message. The unique bit pattern enables any information handling system included on network 110 to be placed in a test mode of operation. The unique bit pattern may be configured to be unique for each network or it may conform to an industry standard. If it is determined in step 220 that there is a match for the unique bit stream included in first packet, then client 130 is placed in a test mode, step 230. In one embodiment, placing client 130 in test mode includes determining whether power is provided to client 130. If it is determined that information handling system 110 has power, a test reset signal is asserted to place client 130 in the test mode. If, however, client 130 is on auxiliary power, fill power is restored and then the test reset is asserted. In one embodiment, the reset may be asserted on a processor included in client 130.

In step 240, a first reply is sent to server 140 confirming the placement of client 130 in the test mode. In one embodiment, the first reply may also include information describing a configuration of client 130, if such information is available and accessible. In step 250, a second packet of information is received from server 140. The second packet is received in response to sending the first reply. The second packet of information is configured to include information that describes at least one test support function and identifies a target device (e.g., a semiconductor device or a PCI option card) included in client 130. In one embodiment, the target device is compliant with and supports the JTAG standard and/or the SCITT test standard.

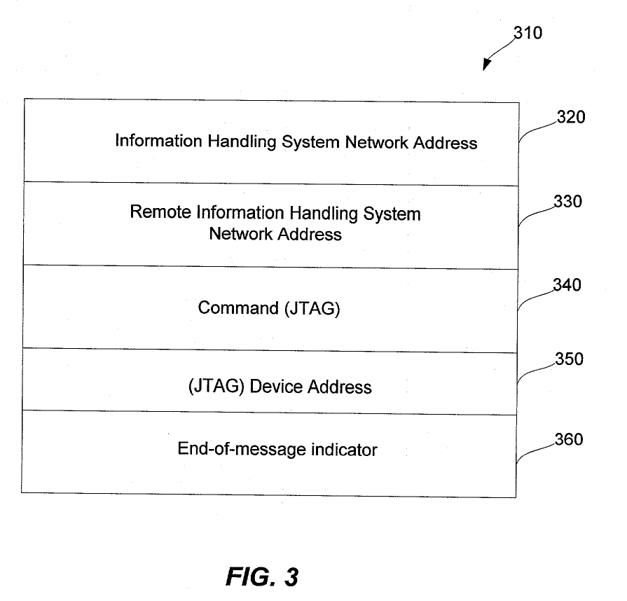

Following the receipt of the second packet, the functions supporting the diagnostic tests as described in the second packet are performed, step 260. These functions may be, for example, forwarding commands and data to client 130. Next, upon completion of the diagnostic test functions in step 270, the diagnostic test results are sent to server 140, step 290. The transmission of packets for performing additional diagnostic tests is repeated until an end-of test packet is received by client 130, decision block 295 and block 297. A more detailed description of steps 260, 270, 290, and 295 is provided subsequently with reference to FIG. 3.

Turning now to FIG. 3, an embodiment of a data structure 310 for an exemplary second packet (e.g., the second packet described in FIG. 2) is illustrated.

First field 320 describes a network address of client 130. A second field 330 includes a network address of server 140. A third field 340 includes a self test command or a bit pattern to be routed to a designated device and/or component on client 130. Third field 340 may also include other support functions for performing the diagnostic test with server 140. A fourth field 350 includes a number to identify a device and/or component designated to receive the self test command or the bit pattern. An N^{th} field 360 may include an end-of-test indicator.

Referring back to step 206 of FIG. 2, the diagnostic test support function is performed by routing at least a portion of the second packet to the target device and/or component. In one embodiment, the routed portion of the second packet includes the test support function and/or test data, e.g., self-test command. The routed portion of the second packet may also include information identifying the target device and/or component. In one embodiment, the routed portion of the second packet is substantially compliant with the JTAG test standard. In step 270, the completion of the diagnostic test support function may be identified by an event such as preparation of a JTAG response packet. The JTAG response packets may be sent to server 140 in step 290. In one embodiment, steps 250, 260, 270 and 290 may be repeated until a last packet, e.g., an end-of-test packet, is received in step 295.

Although shown with fields 320, 330, 340, 350, and 360, data structure 310 may include additional fields or bytes of information arranged in accordance with a predefined format.

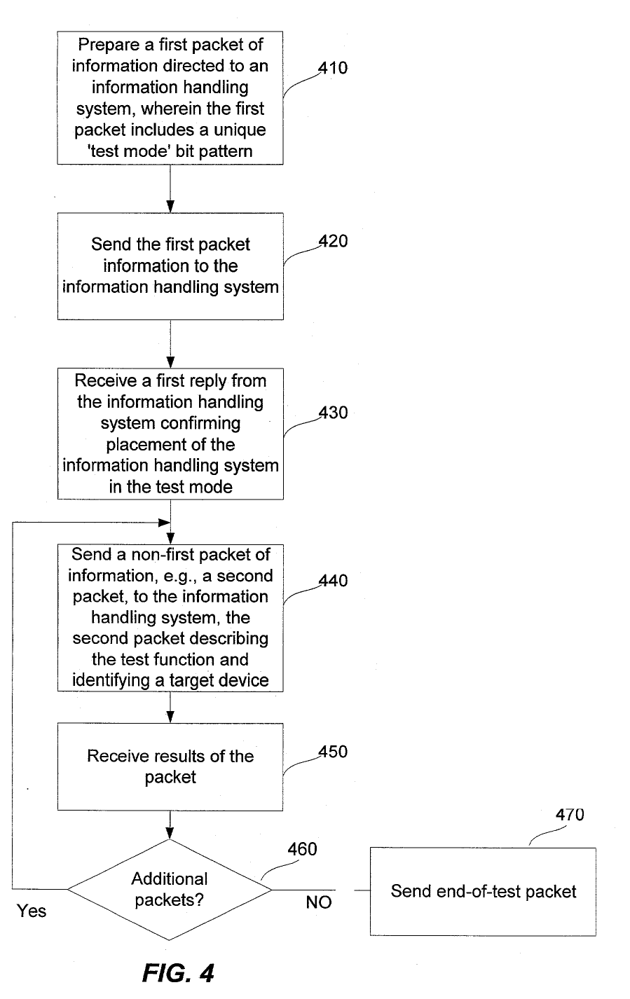

Referring to FIG. 4, a flow chart illustrating a method for requesting performance of a diagnostic test to diagnose an information handling system coupled to a network of information handling systems, is described. In one embodiment, the method in accordance with the present invention may be suitable to be implemented on server 140.

In step 410, a first packet of information for client 130 is prepared. The first packet includes a unique bit pattern and/or a unique message or a command, e.g., similar to a WOL message. The unique bit pattern enables each information handling system included on network 110 to be capable of being placed in a test mode of operation. The unique bit pattern may be configured to be unique for each network or it may conform to an industry standard.

In step 420, the first packet is sent to client 130. In step 430, a first reply is received confirming the placement of client 130 in the test mode. In step 440, another packet of information, e.g., a second packet of information, is sent to client 130 in response to receiving the first reply. The second packet of information is configured to include information that, for example, describes a test function and a target device and/or component included in client 130. In one embodiment, the target device and/or component is compliant with and supports the JTAG standard. In this embodiment, the test function is also in accordance with the JTAG standard. In another embodiment, the test function is consistent with the SCITT test standard.

One embodiment of a data structure 310 of FIG. 3 for the second packet has been described earlier. Referring back to FIG. 4, results of the diagnostic test support functions for the target device and/or component included in client 130 are received in step 450 in response to sending the second packet. In step 460, if additional support functions are to be performed then steps 440 and 450 may be repeated until the test(s) are completed. Otherwise, to signal the end of the testing, an end-of-test packet is sent, step 470.

Client 130 may identify the completion of the diagnostic test support function by information in the response packet by setting a complete bit and/or a data pattern representing observed component pin states. Information describing the results of the diagnostic test support function may be collected while the function is being performed. On completion of the collection of information, the results may be prepared for sending them to the requesting information handling system.

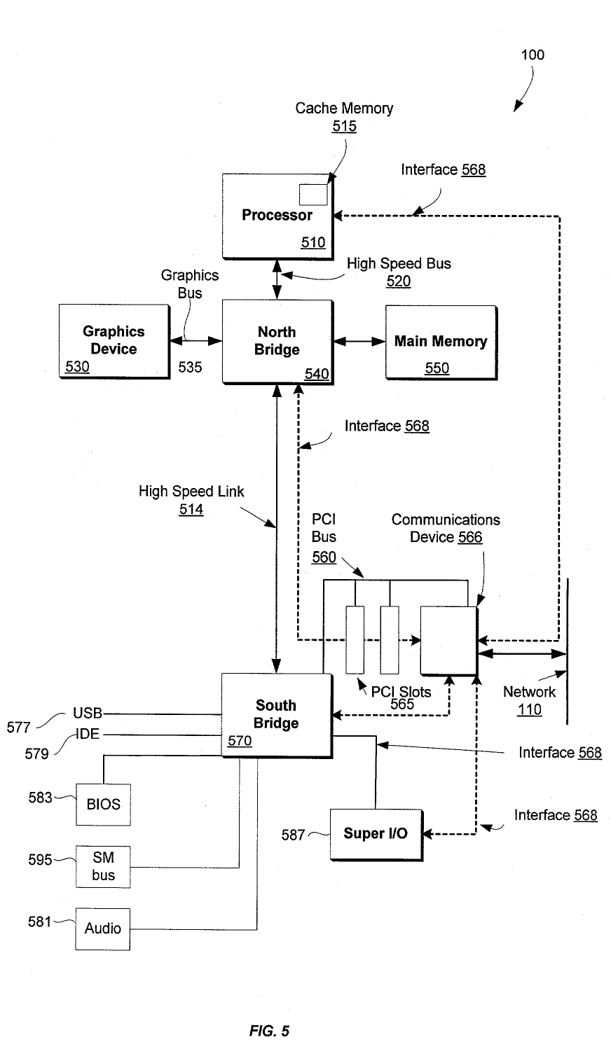

Referring to FIG. 5, one embodiment of client 130 is shown that is suitable for implementing a method for performing a diagnostic test in accordance with the present invention. In one embodiment, client 130 is a computer system. FIG. 5 also illustrates an embodiment of server 140, however, for clarity of the discussion of FIG. 5, reference will be made only to client 130.

Client 130 includes a processor 510, which may also be referred to as a microprocessor. Typical examples of processors included in client 130 are an Intel Pentium class microprocessor or an AMD Athlon™ class microprocessor. Client 130 may include one or more processors. Processor 510 is coupled to a north bridge 540 by a high speed bus 520. In one embodiment, client 130 may include more than one processor coupled to high speed bus 520. A cache memory 515 may be included in processor 510.

North bridge 540, which may also be referred to as a “memory controller hub” or a “memory controller”, is coupled to main system memory 550. North bridge 540 is generally considered an application specific chip set that provides connectivity to various buses, and integrates other system functions such as memory interface. North bridge 540 typically includes functionality to couple main system memory 550 to other devices within client 130. Thus, memory controller functions such as main memory control typically reside in north bridge 540.

Architecture for server 140 may be substantially similar to client 130. However, a few differences may exist. For example, main memory of server 140 may include a memory area, which is employed to store data and code to implement various embodiments of a method for performing a diagnostic test on a target information handling system included in a network of information handling systems. Since client 130 may be potentially experiencing problems, exact contents of main memory 550 may be or may not be known.

North bridge 540 is coupled to the graphics device 530 via a high speed graphics bus 535, e.g., AGP 4× bus. The graphics device 530 typically includes a graphics controller (not shown) coupled to a display panel or a display screen (not shown). For portable information handling systems, the graphics controller may also be coupled to an optional external display device (not shown). In one embodiment, the graphics device 530 also includes a video memory (not shown) which stores information to be displayed on panel display. For portable information handling systems, the panel display is typically an active matrix or passive matrix liquid crystal display (“LCD”) although other display technologies may be used as well.

North bridge 540 is coupled to a south bridge 570 by a high speed link 514. South bridge 570 (also referred to as an I/O controller hub) provides control functions to handle transfers between processor 510 and/or memory 550 and a variety of I/O devices included in client 130.

Client 130 I/O subsystems that are typically connected to south bridge 570 include: integrated drive electronics 579 (“IDE”) hard drive, universal serial bus (“USB”) USB devices 577, audio devices 581, SM bus devices 595, super I/O 587 devices and PCI bus 560. Super I/O 587 controller may interface to a variety of peripheral sub-systems and input/output (I/O) devices such as a keyboard, mouse, IrDA devices, floppy disk drives, serial port devices, and parallel port devices.

PCI bus 560 typically provides an interface for a variety of devices coupled through PCI slots 565. South bridge 570 may also include other functional elements (not shown), such as power management functionality, a real-time clock (RTC), DMA control, interrupt support, and system management bus support.

A Basic Input Output System (“BIOS”) storage device 583 is coupled to south bridge 570 and it incorporates the necessary processor executable code for a variety of low-level system functions and system boot functions. A FLASH memory or other nonvolatile memory may be used as BIOS storage (not shown). A BIOS program (not shown) is usually stored in the BIOS memory. The BIOS program includes software for interaction with the information handling system boot devices such as the keyboard, the mouse, or USB 577 controller. The BIOS device 583 stores the system code which controls some client 130 operations.

In one embodiment, a communications device 566 is coupled to PCI bus 560. In another embodiment, communications device may reside on another bus or may be coupled to south bridge 570. Communications device 566 enables client 130 to communicate with network 110. Other information handling systems (not shown) coupled to network 110, e.g., server 140, are also coupled to client 130 using communications device 566. In one embodiment, communications device 566 may include a receiver and a sender to communicate with network 110. Support functions may be performed by communications device 566. For example, a comparator may be used to determine whether a packet of information received includes a unique bit pattern.

In one embodiment, communications device 566 is also coupled to at least one device, e.g., a target device, included in client 130 that is compliant with a test standard, e.g., a JTAG compliant device. Processor 510 is an example of the JTAG compliant device. The coupling between communications device 566 and JTAG compliant device may be implemented in a variety of ways. In one embodiment, each of the JTAG compliant devices is directly connected to communications device 566 by interface 568 that includes independent serial data pins conforming to the JTAG standard. Thus, communications device 566 also enables network 110 based information handling systems to communicate, e.g., send/receive information, with a target device.

In another embodiment, each of the JTAG compliant devices may be connected to communications device 566 configured as a PCI slot by a bus (not shown). In this embodiment, the bus that may be in the form of a daisy chain may be used for coupling serial data signals. The bus may be configured in accordance with the JTAG standard.

When client 130 is turned on or powered up, client 130 enters a start up phase, also referred to as a boot up phase, during which the information handling system hardware is detected and the operating system is loaded. During the initial boot stages, client 130 BIOS software stored in non-volatile memory is copied into main memory 550 so that it can be executed more quickly. This technique is referred to as “shadowing” or “shadow RAM” as discussed above.

Many other devices or subsystems (not shown) may be connected in a similar manner (e.g., bar code readers, document scanners, digital cameras and so on). Conversely, it is not necessary for all of the devices shown in FIG. 5 to be present to practice the present invention. The devices and subsystems may be interconnected in different ways from that shown in FIG. 5. In a simple form, client 130 may include processor 510 and memory 550. Processor 510 is typically enabled to execute instructions stored in memory 550. The executed instructions typically perform a function. Information handling systems may vary in size, shape, performance, functionality and price. Examples of client 130, which include processor 510 and memory 550, may include all types of computing devices within the range from a pager to a mainframe computer.

In one embodiment, client 130 includes a computer-readable medium having a computer program or client 130 software accessible therefrom. The computer-readable medium may typically include any of the following: a magnetic storage medium, including disk and tape storage medium; an optical storage medium, including compact disks such as CD-ROM, CD-RW, and DVD; a non-volatile memory storage medium; a volatile memory storage medium; and data transmission or communications medium including packets of electronic data, and electromagnetic or fiber optic waves modulated in accordance with the instructions.

The preceding examples are included to demonstrate specific embodiments of the invention. It should be appreciated by those skilled in the art that the techniques disclosed in the examples represent techniques discovered by the inventor to function well in the practice of the invention, and thus may be considered to constitute preferred modes for its practice. However, it should be understood that the invention is not intended to be limited to the particular forms disclosed. Rather, the different aspects of the disclosed compositions and methods may be utilized in various combinations and/or independently. Those skilled in the art should, in light of the present disclosure, appreciate that many changes may be made in the specific embodiments which are disclosed, and still obtain a like or similar result without departing from the spirit and scope of the invention, as defined by the appended claims.

What is claimed is:

1. A method of remotely diagnosing an information handling system, wherein the information handling system is operatively coupled to a network and is responsive to test mode packets, comprising:
transmitting a test mode packet to the information handling system via the network;
transmitting a test command packet to the information handling system via the network, wherein the test command packet includes a test command to be performed on a target device of the information handling system; and
receiving a test result via the network.

2. The method of claim 1, wherein the test mode packet comprises:
a test mode bit pattern, wherein the test mode bit pattern is used to place a device of the information handling system in an operational state.

3. The method of claim 2, further comprising:
determining if the information handling system is on auxiliary power; and
if it is determined that the information handling system is on auxiliary power, restoring power to the information handling system.

4. The method of claim 2, wherein the test mode bit pattern is unique for the information handling system, wherein a plurality of information handling systems including the information handling system are connected to the network.

5. The method of claim 4, wherein the test command packet further comprises:
a first network address, wherein the first network address is a network address of the information handling system;
a second network address, wherein the second network address corresponds to a destination network address for the test results; and
a target device address.

6. The method of claim 1, wherein the test command packet is formatted according to a testing standard.

7. The method of claim 6, wherein the testing standard is at least one of the Joint Test Application Group standard and the Static Component Interconnect Test Technology standard.

8. The method of claim 1, further comprising:
transmitting a plurality of test command packets to the information handling system via the network.

9. The method of claim 1, further comprising:
receiving the test mode packet via the network;
initiating a test mode if the test initiation packet includes a test mode bit pattern;
transmitting a test mode reply packet via the network;
performing a test in response to receiving the test command packet; and
transmitting the test results of the test.

10. A method of remotely diagnosing an information handling system, wherein the information handling system is operatively coupled to a network and is responsive to test mode packets, comprising:
receiving a test mode packet via a network;
receiving a test command packet via the network, the test command packet causing a test to be performed on a target device of the information handling system; and
transmitting the test results via the network.

11. The method of claim 10, wherein the test mode packet comprises:
a test mode bit pattern, wherein the test mode bit pattern is used to place a device of the information handling system in an operational state.

12. The method of claim 11, wherein the test mode bit pattern is unique for each information handling system of a plurality of information handling systems connected to the network, including the information handling system.

13. The method of claim 10, wherein the test command packet comprises:
a test command.

14. The method of claim 13, wherein the test command packet further comprises:
a first network address, wherein the first network address is a network address for the information handling system;
a second network address, wherein the second network address corresponds to a destination network address for the test results; and
a target device address.

15. The method of claim 10, further comprising:
receiving a plurality of test command packets via the network.

16. The method of claim 10, wherein the test command packet is formatted according to a testing standard.

17. The method of claim 16, wherein the testing standard is at least one of the Joint Test Application Group standard and the Static Component Interconnect Test Technology standard.

18. An information handling system, comprising:
a processor;
a memory coupled to the processor; and
a communications device coupled to the processor, the memory, and the network, configured to:
transmit a test mode packet to a remote information handling system via the network;
transmit a test command packet to the remote information handling system via the network, the test command packet causing a test to be performed on a target device of the remote information handling system; and
receive a test result via the network.

19. The information handling system of claim 18, wherein the test command packet comprises:
a test command.

20. The information handling system of claim 19, wherein the test command packet further comprises:
a first network address, wherein the first network address is a network address of the information handling system;
a second network address, wherein the second network address corresponds to a destination network address for the test results; and
the target device address.

21. The information handling system of claim 20, wherein the communications device is further configured to:
transmit a plurality of test command packets via the network.

22. The information handling system of claim 18, wherein the test command packet is formatted according to a testing standard.

23. The information handling system of claim 22, wherein the testing standard is at least one of the Joint Test Application Group standard and the Static Component Interconnect Test Technology standard.
